(19) United States
(12) Patent Application Publication
(10) Pub. No.: US 2002/0145165 A1
(43) Pub. Date: Oct. 10, 2002

(54) Semiconductor device having electrostatic discharge protector and fabricating method thereof

(76) Inventor: Hae Chang Yang, Chungcheongbuk-do (KR)

Correspondence Address: BIRCH STEWART KOLASCH & BIRCH, PO BOX 747, FALLS CHURCH, VA, 22040-0747, US

(21) Appl. No.: 09/988,756

(22) Filed: Nov. 20, 2001

(30) Foreign Application Priority Data
Apr. 4, 2001 (KR) 2001-17929

(51) Int. Cl. H01L 23/62

(52) U.S. Cl. 257/361

(57) ABSTRACT

The semiconductor device having electrostatic discharge protector includes a gate electrode on a first conductive type semiconductor substrate, a second conductive type source area in the semiconductor substrate at one lateral side of the gate electrode, and a second conductive type lightly doped drain area in the semiconductor substrate at the other lateral side of the gate electrode. A second conductive type heavily doped drain area is formed in a portion of the second conductive type lightly doped drain. The second conductive type heavily doped drain area is spaced from the gate electrode, to reduce/eliminate input capacitance of a high speed semiconductor device as well as improve an electrostatic discharge characteristic. A contact of conductive material forms an interface with the second conductive type heavily doped drain area that is recessed into the second conductive type heavily doped drain area.

### BACKGROUND OF THE INVENTION

1. Field of the Invention

The present invention relates to a semiconductor device having an electrostatic discharge protector and fabricating method thereof.

2. Description of Related Art

Generally, a plurality of semiconductor devices manufactured on a wafer are cut by sawing so as to be packaged. When electrostatic discharge(hereinafter abbreviated ESD), which is high voltage amounting over 4000V instantly, generated from a human body is applied to the wafer or package during transportation or fabrication, the semiconductor device is destroyed.

Such an inner circuit damage is caused by Joule's heat generated from electric charges which are inputted to an input pad and outputted to another terminal through an inner circuit. Namely, Joule's heat causes junction spiking and oxide breakage(rupture) and the like, thereby bringing about a damage on the inner circuit.

In order to overcome such a damage, an ESD protection circuit is inserted therein so as to discharge the electric charges injected into the input pad by ESD directly to a terminal of a power supply before the electric charges exit through the inner circuit. Thus, a damage caused on the semiconductor device by ESD is prevented.

An ESD protector is constructed with a field transistor consuming most of the current when ESD is applied between an input pad and an inner circuit, a gate ground NMOS transistor protecting a gate insulating layer of the inner circuit, and a resistor preventing excessive current from flowing into the NMOS transistor.

In the ESD protection field transistor, n+ impurity diffusion areas, which become source and drain areas of the field transistor, are formed at both sides of a device isolating layer on a semiconductor substrate having a p-type well. The n+ impurity diffusion area at the one side is connected to an input pin, and the other n+ impurity diffusion area is connected to VSS.

Such an ESD protector itself is destroyed when ESD is applied thereto, in which the drain area of the field transistor is mainly destroyed. This is because the drain area is directly connected to the input pin.

A semiconductor device having an ESD protector and a fabricating method thereof are explained by referring to the attached drawings as follows.

FIG. 1A illustrates a layout of an ESD transistor of an ESD protector according to the prior art, and FIG. 1B illustrates a cross-sectional view of the ESD transistor bisected along line I-I′.

Referring to FIG. 1A and FIG. 1B, after defining an active area and a field area on a semiconductor substrate 10 having a p-type well, a device isolating layer 11 is formed in the field area of the semiconductor substrate 10.

Then, a gate electrode 13a having a gate insulating layer 12 there under is formed in one direction on the active area of the semiconductor substrate 10 isolated by the device isolation layer 11. And, source and drain areas 15 and 16 are formed on the semiconductor substrate 10 at both lateral sides of the gate electrode 13a, respectively.

Successively, a first insulating interlayer 17, having a plurality of first contact holes 18a and 18b exposing predetermined surface portions of the source and drain areas 15 and 16, is formed on the substrate 10. In this case, the first contact hole 18b on the drain area 16 is formed to leave at least a 2 interval from the gate electrode 13a.

If the interval between the gate electrode 13a and the first contact hole 18b is short enough to have a small resistance, the gate insulating layer 12 on a transistor channel part is broken by ESD from the gate electrode 13a.

And, the interval between the gate electrode 13a and first contact hole 18b is a major parameter of an input capacitance.

A first conductive layer 19 is formed in the first contact holes 18a and 18b, and a first metal layer pattern 20 is formed not to be overlapped with the gate electrode 13a but to be connected with the first conductive layer 19 on the source and drain areas 15 and 16. In this case, the first conductive layer 19 is formed of tungsten.

A second insulating layer 21 having second contact holes 22a and 22b exposing predetermined portions of the first metal layer pattern 20. A second conductive layer 23 is then formed in the second contact holes 22a and 22b. In this case, the second contact hole 22b in the drain area 16 is formed not to be overlapped with the first contact hole 18b. And, the second conductive layer 23 is formed of tungsten.

Subsequently, a second metal layer pattern 24 is formed over the source and drain areas 15 and 16 so as not to be overlapped with the gate electrode 13a but to be connected to the second conductive layer 23.

In this case, an input capacitance occupies 80 to 90% of an area size C×D of the drain area in FIG. 1A.

Operation of the above-constructed ESD device is explained by the bipolar operation of a field transistor.

When a high voltage is applied to the second metal layer pattern 24 formed over the drain area 16, avalanche breakdown occurs in a drain area of a gate ground transistor(not shown in the drawing) connected to a resistor.

A current flows through a junction of the field transistor after the junction breakdown. The current flow into the substrate 10 due to the junction breakdown is drained to a ground terminal(source area 15). In this case, when the current flow into the substrate 10 becomes large, a voltage difference is produced by a resistance of the substrate 10, which is an intrinsic resistor having a large resistance. Thus, the source area 15 of the field transistor makes a substrate voltage increase.

In this case, the source area 15 of the field transistor is an emitter of a bipolar transistor, the substrate 10 is a base, and the drain area 16 is a collector so as to carry out the bipolar operation. This is because an emitter-base junction becomes forward biased owing to the increasing base voltage of the bipolar transistor.

FIGS. 2A to FIGS. 2F illustrate cross-sectional views of fabricating an ESD transistor according to the prior art.

Referring to FIG. 2A, after an active area and a field area have been defined on a semiconductor substrate 10 having a p-type well, a trench is formed to have a predetermined depth in the substrate 10 by removing selectively the field area. An insulating layer is formed on the semiconductor substrate 10 including the trench.

Subsequently, etch-back or CMP is carried out on an entire surface of the semiconductor substrate 10 so that the insulating layer remains only in the trench. Thus, a device insulating layer 11 having an STI(shallow trench isolation) structure is formed. A gate insulating layer 12 and a polysilicon layer 13 for forming a gate electrode are then formed on the semiconductor substrate 10.

After a photoresist has been formed on the polysilicon layer 13, exposure and development are carried out on the photoresist so as to form a patterned photoresist 14 defining a gate area.

Referring to FIG. 2B, a gate electrode 13a is formed by removing the polysilicon layer 13 and gate insulating layer 12 selectively using the patterned photoresist 14 as a mask.

Referring to FIG. 2C, after the patterned photoresist 14 has been removed, source and drain areas 15 and 16 are formed on the semiconductor substrate 10 at both lateral sides of the gate electrode 13a respectively by carrying out impurity ion implantation on an entire surface of the semiconductor substrate 10 using the gate electrode 13a as a mask.

In order to secure a sufficient drain resistance, a salicide layer is formed using a salicide protection mask (not shown in the drawing). And, the salicide layer (not shown in the drawing) is formed on a surface of the substrate, where gate electrodes and source/drain areas of other transistors are formed, by forming a Ti or Co layer on an entire surface of the semiconductor substrate 10 except the area where an ESD transistor is formed. Namely, the salicide layer is formed not to cover an area where the ESD transistor is to be formed.

Referring to FIG. 2D, a first insulating interlayer 17 is formed on an entire surface of the semiconductor substrate including the gate electrode 13a. A plurality of first contact holes 18a and 18b are then formed by removing the first insulating interlayer 17 selectively so as to expose predetermined portions of the source and drain areas 15 and 16. In this case, the first contact hole 18b formed in the drain area 16 is formed to leave an interval at least 2 from the gate electrode 13a.

Referring to FIG. 2E, a first conductive layer 19 is formed on the first insulating layer 17 including the first contact holes 18a and 18b. Then, etch-back or CMP is carried out on the first conductive layer 19 so as to leave the first conductive layer 19 inside the first contact holes 18a and 18b only. In this case, the first conductive layer 19 is formed of tungsten.

A first metal layer is deposited on the first insulating interlayer 17 including the first conductive layer 19. A first metal layer pattern 20 is then formed on the source and drain areas 15 and 16 by removing portions of the first metal layer.

Still referring to FIG. 2E, a second insulating interlayer 21 is formed on the first metal layer pattern 20. A plurality of second contact holes 22a and 22b are formed by removing the second insulating interlayer 21 selectively so as to expose predetermined portions of the first metal layer pattern 20. In this case, the second contact holes 22a and 22b are formed not to overlap with the first contact hole 18b.

Subsequently, as shown in FIG. 2F, a second conductive layer 23 is formed inside the second contact holes 22. A second metal layer pattern 24 is formed selectively on the second insulating interlayer 21 including the second conductive layer 23. In this case, the second conductive layer 23 is formed of tungsten.

Then, a third metal layer pattern is formed after a contact hole is formed to expose the gate electrode for forming a wire, which is not shown in the drawing.

Unfortunately, the semiconductor device having the ESD protector and fabricating method thereof according to the prior art has the problems as follows.

An interval between a contact and a gate electrode for securing a resistance of a drain area is a major parameter for the ESD protector according to the prior art. Yet, the resistance is too small to prevent a gate insulating layer on a channel area of a transistor from being destroyed when ESD is applied to the gate electrode.

Therefore, the interval between the contact and gate electrode is designed long enough to secure the resistance of the drain area.

Thus, an area size of the drain area is so wide that an input capacitance increases when the interval between the contact and gate electrode is designed long enough to secure the resistance of the drain area.

As a result, the increase of the input capacitance delays data input/output so as to interrupt the high speed of device operation.

Moreover, a CSP(chip scale package) type high-speed-operating device is vulnerable to CDM(charged device mode).

### SUMMARY OF THE INVENTION

Accordingly, the present invention is directed to a semiconductor device having an electrostatic discharge protector and fabricating method thereof that substantially obviates one or more of the problems due to limitations and disadvantages of the related art.

The object of the present invention is to provide a semiconductor device having an electrostatic discharge protector and fabricating method thereof enabling to reduce/eliminate input capacitance of a high speed semiconductor device as well as improve an electrostatic discharge characteristic by reducing an interval between a contact and a gate electrode when the contact is formed to secure a resistance of a drain area of an ESD transistor.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages, and in accordance with the purpose of the present invention as embodied and broadly described, a semiconductor device having an electrostatic discharge protector according to the present invention includes a gate electrode on a first conductive type semiconductor substrate, a second conductive type source area in the semiconductor substrate at a first lateral side of the gate electrode, a second conductive type lightly doped drain area in the semiconductor substrate at a second lateral side of the gate electrode, and a second conductive type heavily doped drain area in the second conductive type lightly doped drain, the second conductivity type heavily doped drain area being spaced from the gate electrode.

Preferably, the second conductive type heavily doped drain area is formed deeper into the substrate than the second conductive type lightly doped drain area.

Preferably, the present invention further includes a contact for a wiring process for the second conductive type heavily doped drain area.

Preferably, a contact interface of the contact for the second conductive type heavily doped drain area is recessed into a surface of the second conductive type heavily doped drain area.

Preferably, the second conductive type heavily doped drain area is spaced from the gate electrode so as to secure a desired resistance.

Preferably, the first conductive type semiconductor substrate forms a p-type well using boron of which concentration is 1E17 to 3E17 ions/cm³, the second conductive type lightly doped drain area is doped with phosphorus of which concentration is 1E18 ions/cm³, and the second conductive type source/drain areas are doped with arsenic at a concentration over 1E20 ions/cm³.

Preferably, a device isolation layer is formed in a field area of the semiconductor substrate defined by the field area and an active area.

More preferably, the device isolation layer has a shallow trench isolation(STI) structure.

In another aspect according to the present invention, a method of fabricating a semiconductor device having electrostatic discharge protector includes the steps of forming a gate electrode on a first conductive type semiconductor substrate, forming a second conductive type lightly doped source area in the semiconductor substrate at a first lateral side of the gate electrode and a second conductive type lightly doped drain area in the semiconductor substrate at a second lateral side of the gate electrode, and forming a second conductive type heavily doped source area at the first lateral side of the gate electrode and a second conductive type heavily doped drain area in the second conductive type lightly doped drain, the second conductivity type heavily doped drain area being spaced from the gate electrode.

Preferably, the step of forming the second conductive type lightly doped source and drain areas forms the second conductive type lightly doped source and drain areas using the gate electrode as a mask; and the step of forming the second heavily doped source and drain areas includes forming a photoresist pattern exposing the second conductive type lightly doped source area and a predetermined portion of the second conductive type lightly doped drain area, and simultaneously forming the second conductive type heavily doped source area and the second conductive type heavily doped drain area.

Preferably, the second conductive type heavily doped drain area is formed deeper into the substrate than the second conductive type lightly doped drain area.

Preferably, the method further includes the steps of forming an insulating interlayer over the substrate, and forming a contact hole exposing a portion of the second conductive type heavily doped drain area by selectively removing the insulating interlayer.

More preferably, a contact interface of the contact hole formed in the second conductive type heavily doped drain area is recessed into a surface of the second conductive type heavily doped drain area.

Preferably, the second conductive type heavily doped drain area is spaced from the gate electrode so as to secure a desired resistance.

Preferably, the first conductive type semiconductor substrate forms a p-type well using boron of which concentration is 1E17 to 3E17 ions/cm³, the second conductive type lightly doped drain area is doped with phosphorus of which concentration is 1E18 ions/cm³, and the second conductive type source/drain areas are doped with arsenic at a concentration over 1E20 ions/cm³.

Preferably, a device isolation layer, after field and active areas are defined on the substrate, is formed in the field area of the semiconductor substrate.

More preferably, the device isolation layer has a shallow trench isolation(STI) structure.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1A illustrates a layout of an ESD transistor of an ESD protector according to the prior art;

FIG. 1B illustrates a cross-sectional view of the ESD transistor bisected along line I-I′;

FIGS. 2A to FIGS. 2F illustrate cross-sectional views of fabricating an ESD transistor according to the prior art;

FIG. 3A illustrates a layout of an ESD transistor of an ESD protector according to an embodiment of the present invention;

FIG. 3B illustrates a cross-sectional view of the ESD transistor bisected along line III-III′; and

FIGS. 4A to FIGS. 4F illustrate cross-sectional views of fabricating an ESD transistor according to an embodiment of the present invention.

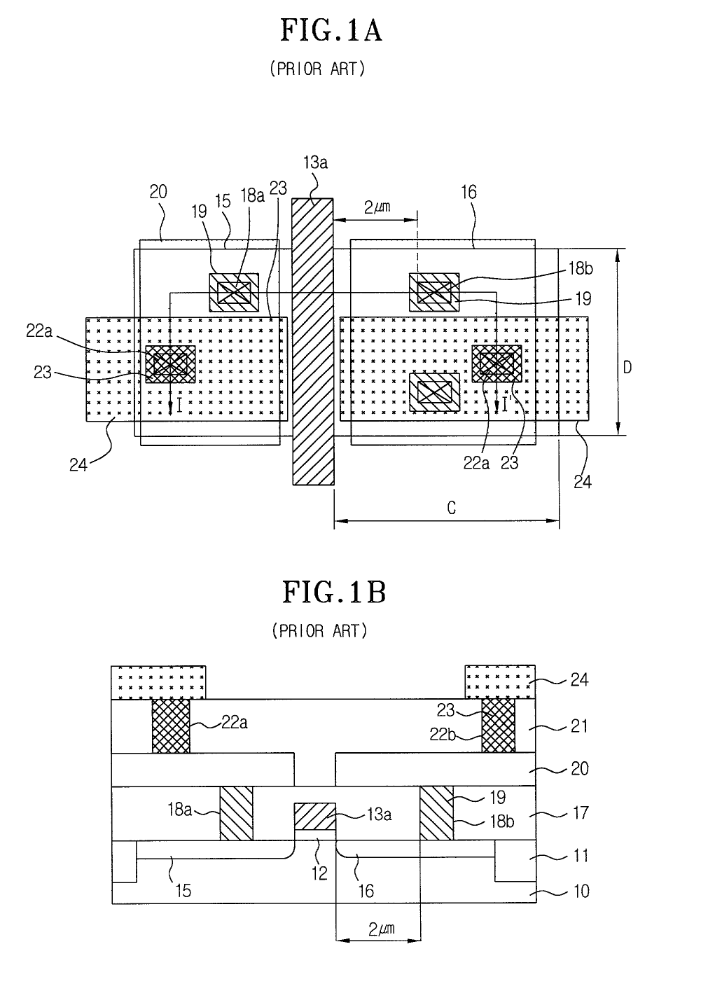

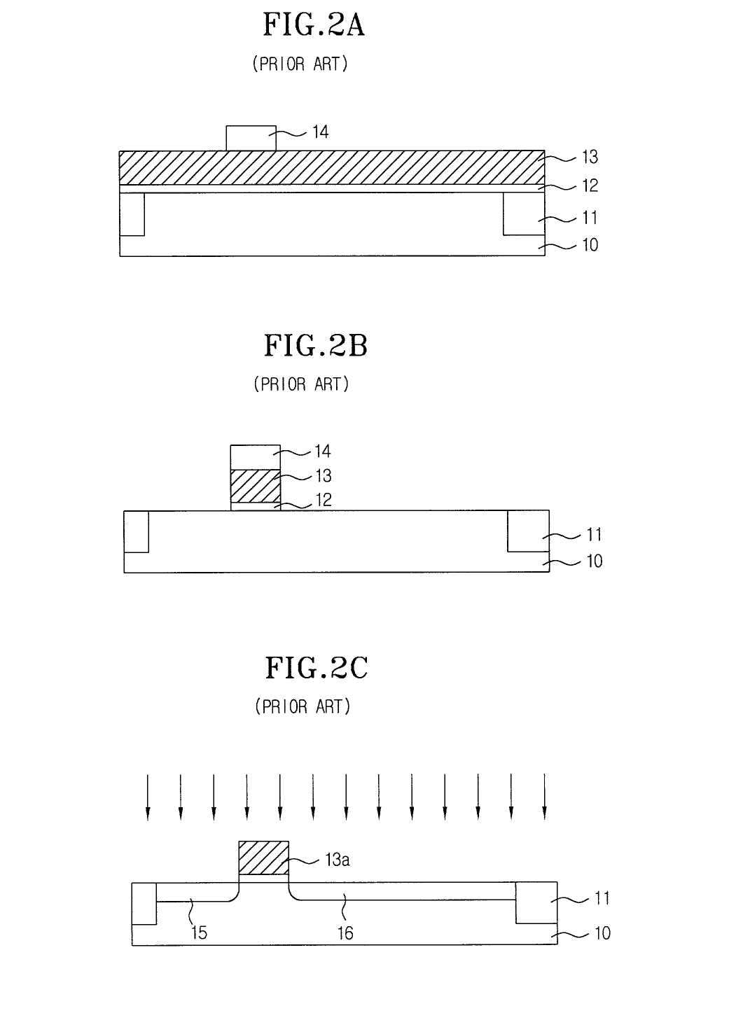

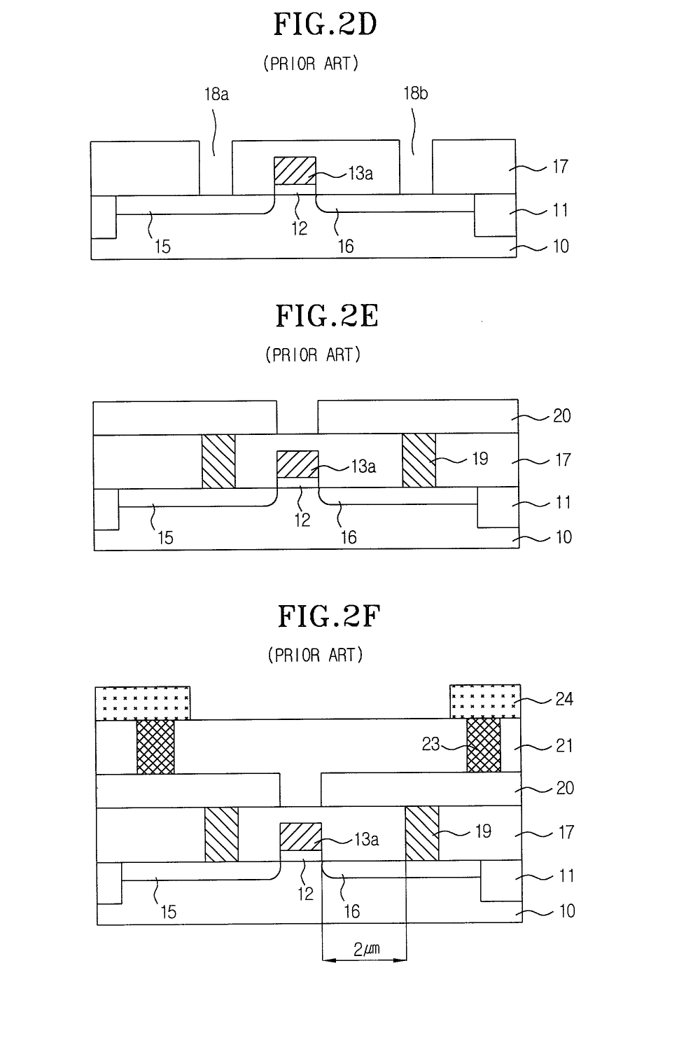

### DETAILED DESCRIPTION OF THE PREFERRED EMBODIMENTS

Reference will now be made in detail to the preferred embodiments of the present invention, examples of which are illustrated in the accompanying drawings. Where possible, the same reference numerals will be used to illustrate like elements throughout the specification.

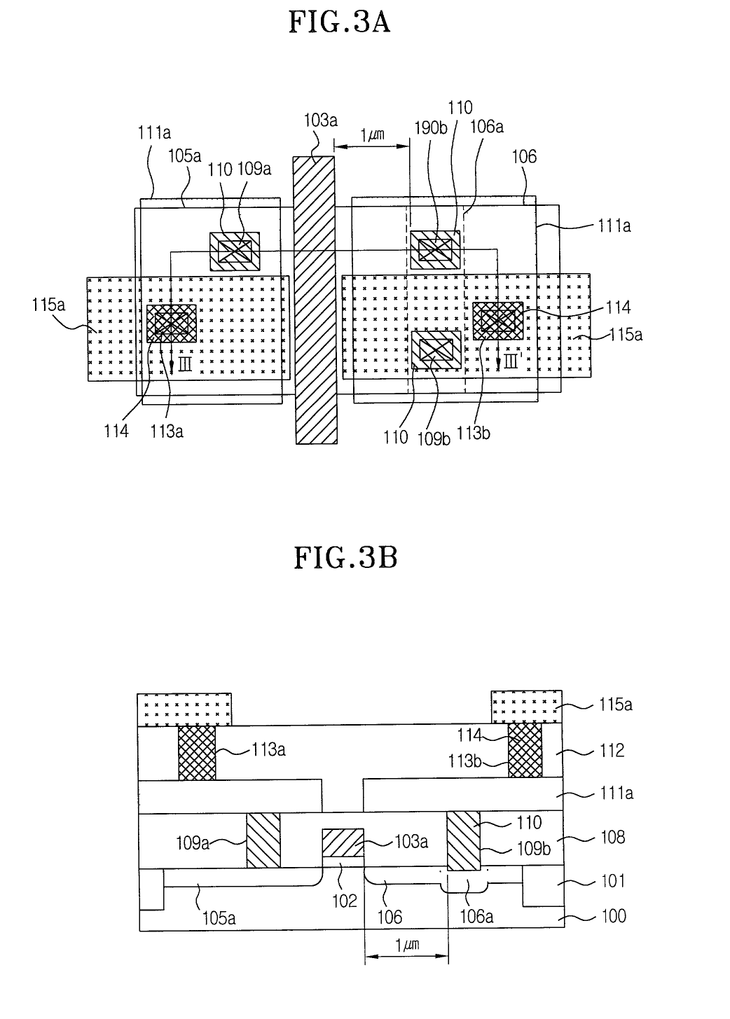

FIG. 3A illustrates a layout of an ESD transistor of an ESD protector according to an embodiment of the present invention and FIG. 3B illustrates a cross-sectional view of the ESD transistor bisected along line III-III′.

Referring to FIG. 3A and FIG. 3B, a device isolating layer 101 having an STI(shallow trench isolation) structure is formed in a field area of a semiconductor substrate 100 where an active area and the field area are defined.

Then, a gate electrode 103a having a gate insulating layer 12 underneath is formed in one direction on the active area of the semiconductor substrate 100. And, a heavily doped source area 105a is formed at one lateral side of the gate electrode 103a of the semiconductor substrate 100.

A lightly doped drain area 106 is formed at the other lateral side of the gate electrode 103a of the semiconductor substrate 100. Additionally, a heavily doped drain area 106a is formed in the lightly doped drain area 106 leaving a predetermined interval far from the gate electrode 103a. In this case, the heavily doped drain area 106a is formed to provide a sufficient interval to secure a necessary resistance from the gate electrode 103a. In addition, the heavily doped drain area 106a is formed deeper than the lightly doped drain area 106.

When the semiconductor substrate 100 is a p-type substrate, the heavily doped source area 105a and the lightly/heavily doped drain areas 106 and 106a are doped with n-type impurities. Otherwise, the heavily doped source area 105a and the lightly/heavily doped drain areas 106 and 106a are doped with p-type impurities.

Successively, a first insulating interlayer 107 having a plurality of first contact holes 109a and 109b exposing predetermined surface portions of the heavily doped source and drain areas 105a and 106a is formed on an entire surface of the substrate 100. In this case, a contact interface of the first contact hole 109b is formed deeper than a surface of the heavily doped drain area 106a.

A first conductive layer 110 is formed in the first contact holes 109a and 109b. And, a first metal layer pattern 111 is formed on the first insulating interlayer 107 including the first conductive layer 110, and over but not in contact with the gate electrode 103a. In this case, the first conductive layer 103a is formed of tungsten.

A second insulating layer 112 having second contact holes 113a and 113b exposing predetermined portions of the first metal layer pattern 111a. A second conductive layer 114 is then formed in the second contact holes 113a and 113b only. In this case, the second contact holes 113a and 113b are formed not to be overlapped with the first contact holes 109a and 109b. And, the second conductive layer 114 is formed of tungsten.

Subsequently, a second metal layer pattern 115 is formed selectively on the second insulating layer 112 including the second conductive layer 114, and over but not in contact with the gate electrode 103a.

Then, a third metal layer pattern (not shown) is formed after a contact hole (not shown) is formed to expose the gate electrode 103a for forming a wire, which is not shown in the drawing.

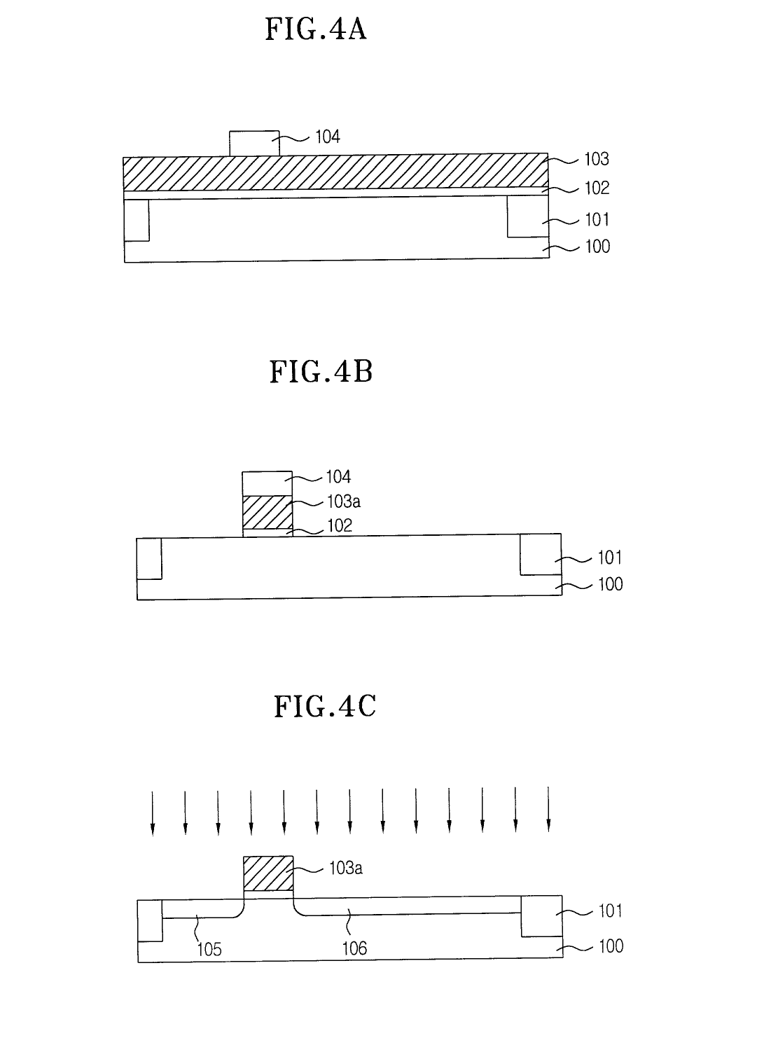

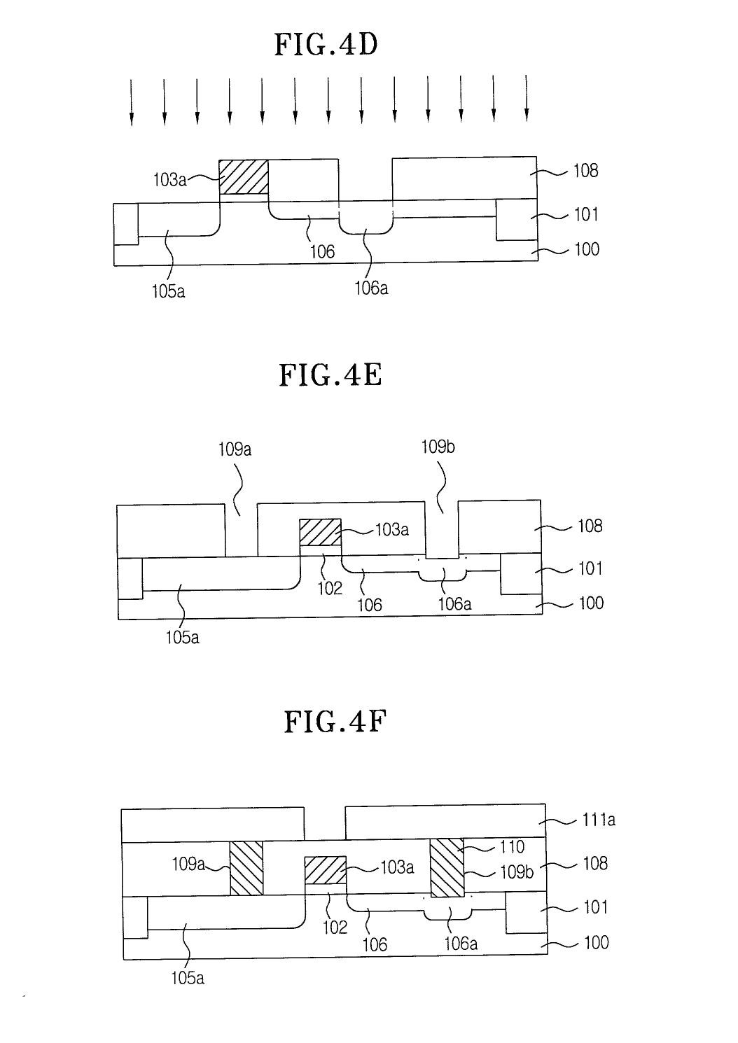

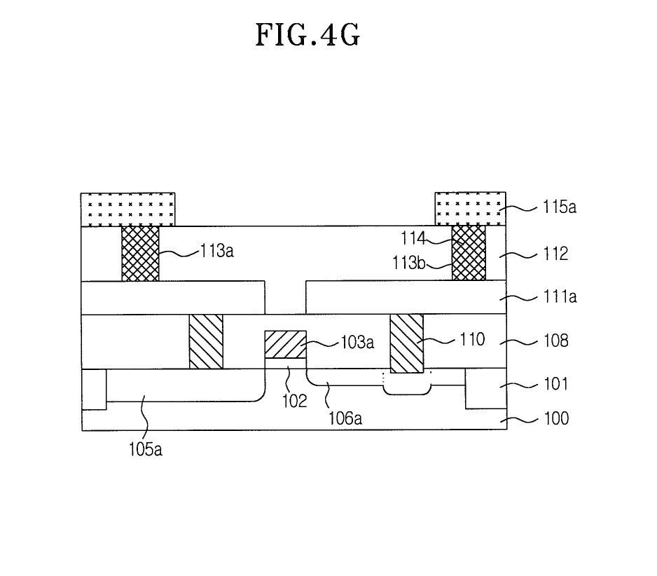

FIGS. 4A to FIGS. 4F illustrate cross-sectional views of fabricating an ESD transistor according to an embodiment of the present invention.

Referring to FIG. 4A, after an active area and a field area have been defined on a semiconductor substrate 100 having a p-type well, a trench is formed to have a predetermined depth in the substrate 100 by removing selectively the field area. An insulating layer(not shown in the drawing) is formed on the semiconductor substrate 100 including the trench. In this case, the p-type well of the semiconductor substrate 100 is formed using boron and impurity density of the p-type well is 1E17 to 3E17 ions/cm³.

Subsequently, etch-back or CMP is carried out on an entire surface of the semiconductor substrate 100 so that the insulating layer remains only inside the trench. Thus, a device insulating layer 101 having an STI(shallow trench isolation) structure is formed. A gate insulating layer 102 and a polysilicon layer 103 for forming a gate electrode are then formed on the semiconductor substrate 100.

After a first photoresist has been formed on the polysilicon layer 103, exposure and development are carried out on the first photoresist so as to form a first patterned photoresist 104 defining a gate area.

Referring to FIG. 4B, a gate electrode 103a is formed by removing the polysilicon layer 103 and gate insulating layer 102 selectively using the first patterned photoresist 104 as a mask.

Referring to FIG. 4C, after the first patterned photoresist 104 has been removed, a lightly doped source area 105 and a lightly doped drain area 106 are formed in the semiconductor substrate 100 at both lateral sides of the gate electrode 103a respectively by lightly carrying out impurity ion implantation on an entire surface of the semiconductor substrate 100 using the gate electrode 103a as a mask. In this case, the impurity ions for the lightly doped source/drain are phosphorus ions and the impurity concentration is 1E18 ions/cm³.

In order to secure a sufficient drain resistance, a salicide layer is formed using a salicide protection mask(not shown in the drawing). And, the salicide layer(not shown in the drawing) is formed on a surface of the substrate, where gate electrodes and source/drain areas of other transistors are formed, by forming a Ti or Co layer on an entire surface of the semiconductor substrate 100 except the area where an ESD transistor is formed. Namely, the salicide layer is formed not to cover an area where the ESD transistor is to be formed.

Referring to FIG. 4D, after a second photoresist has been formed on an entire surface of the semiconductor substrate 100, exposure and development are carried out on the second photoresist so as to form a second patterned photoresist 107 exposing portions of the lightly doped source and drain areas 105a and 106.

Subsequently, by implanting impurity ions for heavily doped source/drain using the second patterned photoresist 107 and gate electrode 103a as a mask, a heavily doped source area 105a is formed at one lateral side of the gate electrode 103a and a heavily doped drain area 106a is formed to be located a predetermined interval from the gate electrode 103a.

In this case, the heavily doped drain area 106a is formed at a sufficient interval from the gate electrode 103a to secure a necessary resistance from the gate electrode 103a. In addition, the heavily doped drain area 106a is formed deeper than the lightly doped drain area 106.

The impurity for the heavily doped source/drain is arsenic, and the concentration is about 1E20 ions/cm3.

When the semiconductor substrate 100 is a p-type substrate, the heavily doped source area 105a and the lightly/heavily doped drain areas 106 and 106a are doped with n-type impurities. Otherwise, the heavily doped source area 105a and the lightly/heavily doped drain areas 106 and 106a are doped with p-type impurities.

Referring to FIG. 4E, after the second patterned photoresist 107 has been removed, a first insulating interlayer 108 is formed on an entire surface of the semiconductor substrate 100 including the gate electrode 103a. A plurality of first contact holes 109a and 109b are then formed by removing the first insulating interlayer 108 selectively so as to expose predetermined portions of the heavily doped source and drain areas 105a and 106a.

In this case, the first contact hole 109b exposing the heavily doped drain area 106 has the interval, which is shorter than that of the prior art, from the gate electrode 103a.

In this case, a contact interface of the first contact hole 109b formed in the heavily doped drain area 106a is formed deeper than a surface of the heavily doped drain area 106a.

Therefore, a vertical resistance at the contact interface of the first contact hole 109b is reduced.

Referring to FIG. 4F, a first conductive layer 110 is formed on the first insulating layer 108 including the first contact holes 109a and 109b. Then, etch-back or CMP is carried out on the first conductive layer 110 so as to leave the first conductive layer 110 inside the first contact holes 109a and 109b only. In this case, the first conductive layer 110 is formed of tungsten.

A first metal layer is deposited on the first insulating interlayer 108 including the first conductive layer 110. A first metal layer pattern 111 is then formed by removing the first metal layer 111 selectively. The first metal layer 111 is over but not in contact with the gate electrode 103a.

A second insulating interlayer 112 is formed on the first metal layer pattern 111. A plurality of second contact holes 113a and 113b are formed by removing the second insulating interlayer 112 selectively so as to expose predetermined portions of the first metal layer pattern 111.

Subsequently, as shown in FIG. 4G, a second conductive layer 114 is formed inside the second contact holes 113a and 113b. A second metal layer pattern 115 is formed selectively on the second insulating interlayer 112 including the second conductive layer 114. The second metal layer pattern 115 covers but does not contact the gate electrode 103a.

Then, a third metal layer pattern (not shown) is formed after a contact hole (not shown) is formed to expose the gate electrode 103a for forming a wire, which is not shown in the drawing.

Therefore, a semiconductor device having electrostatic discharge protector and fabricating method thereof enables to reduce or eliminate an input capacitance since the reduced size of the ESD protector is realized.

Accordingly, the present invention enables to design a device having low input capacitance as well as excellent ESD characteristics by settling the reciprocality between the ESD characteristics and input capacitance.

Moreover, when maintaining the same input capacitance of the related art, the present invention is available for high-sped-operation devices such as DDR, Rambers DRAM, SRAM and the like by increasing twice the size of the ESD protector.

The foregoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

what is claimed is:

1. A semiconductor device having an electrostatic discharge protector comprising:
a gate electrode on a first conductive type semiconductor substrate;
a second conductive type source area in the semiconductor substrate at a first lateral side of the gate electrode;
a second conductive type lightly doped drain area in the semiconductor substrate at a second lateral side of the gate electrode; and
a second conductive type heavily doped drain area in the second conductive type lightly doped drain, the second conductivity type heavily doped drain area being spaced from the gate electrode.

2. The semiconductor device having an electrostatic discharge protector of claim 1, wherein the second conductive type heavily doped drain area is formed deeper into the semiconductor substrate than the second conductive type lightly doped drain area.

3. The semiconductor device having an electrostatic discharge protector of claim 1, further comprising:
a contact to the second conductive type heavily doped drain area.

4. The semiconductor device having an electrostatic discharge protector of claim 3, wherein a contact interface of the contact is recessed into a surface of the second conductive type heavily doped drain area.

5. The semiconductor device having an electrostatic discharge protector of claim 1, wherein the second conductive type heavily doped drain area is spaced from the gate electrode by less than______ and greater than______.

6. The semiconductor device having an electrostatic discharge protector of claim 1, wherein the second conductive type heavily doped drain area is spaced from the gate electrode to provide a resistance there between of at least______.

7. The semiconductor device having an electrostatic discharge protector of claim 1, wherein
the first conductive type semiconductor substrate forms a p-type well using boron, of which concentration is 1E17 to 3E17 ions/cm³;
the second conductive type lightly doped drain area is doped with phosphorus, of which concentration is 1E18 ions/cm³; and
the second conductive type source area and the second conductive type heavily doped drain area are doped with arsenic at a concentration over 1E20 ions/cm³.

8. The semiconductor device having an electrostatic discharge protector of claim 1, wherein a device isolation layer is formed in a field area of the semiconductor substrate defined by the field area and an active area.

9. The semiconductor device having an electrostatic discharge protector of claim 7, wherein the device isolation layer has a shallow trench isolation (STI) structure.

10. A method of fabricating a semiconductor device having an electrostatic discharge protector comprising the steps of:
forming a gate electrode on a first conductive type semiconductor substrate;
forming a second conductive type lightly doped source area in the semiconductor substrate at a first lateral side of the gate electrode and a second conductive type lightly doped drain area in the semiconductor substrate at a second lateral side of the gate electrode; and
forming a second conductive type heavily doped source area at the one lateral side of the gate electrode and a second conductive type heavily doped drain area in the second conductive type lightly doped drain area, the second conductivity type heavily doped drain area being spaced from the gate electrode.

11. The method of claim 10, wherein
the step of forming the second conductive type lightly doped source and drain areas forms the second conductive type lightly doped sources and drain areas using the gate electrode as a mask; and
the step of forming the second heavily doped source and drain areas includes,
forming a photoresist pattern exposing the second conductive type lightly doped source area and a predetermined portion of the second conductive type lightly doped drain area, and
simultaneously forming the second conductive type heavily doped source area and the second conductive type heavily doped drain area using the photoresist pattern as a mask.

12. The method of claim 10, wherein the second conductive type heavily doped drain area is formed deeper into the semiconductor substrate than the second conductive type lightly doped drain area.

13. The method of claim 10, after forming the second conductive type heavily doped source and drain areas, the method further comprising the steps of:
forming an insulating interlayer over the semiconductor substrate; and
forming a contact hole exposing a portion of the second conductive type heavily doped drain area by selectively removing the insulating interlayer.

14. The method of claim 13, wherein a contact interface of the contact hole formed in the second conductive type heavily doped drain area is recessed into a surface of the second conductive type heavily doped drain area.

15. The method of claim 14, further comprising:
filling the contact hole with a conductive material.

16. The method of claim 10, wherein the second conductive type heavily doped drain area is spaced from the gate electrode by less than______ and greater than______.

17. The method of claim 10, wherein the second conductive type heavily doped drain area is spaced from the gate electrode to provide a resistance there between of at least______.

18. The method of claim 10, wherein
the first conductive type semiconductor substrate forms a p-type well using boron, of which concentration is 1E17 to 3E17 ions/cm³;
the second conductive type lightly doped drain area is doped with phosphorus, of which concentration is 1E18 ions/cm³; and
the second conductive type source and drain areas are doped with arsenic at a concentration over 1E20 ions/cm³.

19. The method of claim 10, further comprising:
forming a device isolation layer, after field and active areas are defined on the substrate, in the field area of the semiconductor substrate.

20. The method of claim 19, wherein the device isolation layer has a shallow trench isolation (STI) structure.
